(19) United States
(12) Patent Application Publication
(10) Pub. No.: US 2008/0019098 A1
(43) Pub. Date: Jan. 24, 2008

(54) Diamond composite heat spreader and associated methods

(76) Inventor: Chien-Min Sung, Tansui (TW)

Correspondence Address: THORPE NORTH & WESTERN, LLP., 8180 SOUTH 700 EAST, SUITE 350, SANDY, UT, 84070, US

(21) Appl. No.: 11/891,298

(22) Filed: Aug. 8, 2007

Related U.S. Application Data
(63) Continuation-in-part of application No. 11/266,015, filed on Nov. 2, 2005.
(63) Continuation-in-part of application No. 11/056,339, filed on Feb. 10, 2005.
Application No. 11/056,339 is a continuation-in-part of application No. 10/775,543, filed on Feb. 9, 2004, now Pat. No. 6,987,318.
Application No. 10/775,543 is a continuation-in-part of application No. 10/453,469, filed on Jun. 2, 2003, now Pat. No. 6,984,888.
Application No. 10/775,543 is a continuation-in-part of application No. 10/270,018, filed on Oct. 11, 2002, now Pat. No. 7,173,334.
(60) Provisional application No. 60/681,677, filed on May 16, 2005.

(51) Int. Cl. H05K 7/20

(52) U.S. Cl. 361/706; 361/705

(57) ABSTRACT

A diamond composite heat spreader includes a plurality of discrete and packed diamond particles. The heat spreader further includes sintered polycrystalline diamond dispersed throughout the plurality of diamond particles. The sintered polycrystalline diamond at least partially cements the plurality of diamond particles together.

### PRIORITY INFORMATION

This application is a continuation-in-part of U.S. Pat. No. 11/266,015, filed Nov. 2, 2005, which claims the benefit of earlier filed U.S. Provisional Application No. 60/681,677, filed May 16, 2005, which is incorporated herein by reference. This application is also a continuation-in-part of U.S. patent application Ser. No. 11/056,339, filed Feb. 10, 2005, which is a continuation-in-part of U.S. patent application Ser. No. 10/775,543, filed Feb. 9, 2004, which is a continuation-in-part of U.S. patent application Ser. No. 10/453,469, filed Jun. 2, 2003 and of U.S. patent application Ser. No. 10/270,018, filed Oct. 11, 2002, which are each incorporated by reference herein.

### FIELD OF THE INVENTION

The present invention relates to carbonaceous composite devices and systems that can be used to conduct or absorb heat away from a heat source. Accordingly, the present invention involves the fields of chemistry, physics, semiconductor technology, and materials science.

### BACKGROUND OF THE INVENTION

Progress in the semiconductor industry has been following the trend of Moore's Law that was proposed in 1965 by then Intel's cofounder Gordon Moore. This trend requires that the capability of integrated circuits (IC) or, in general, semiconductor chips, doubles every 18 months. Thus, the number of transistors on conventional central processing units is approaching and exceeding 100 million.

As this densification of circuitry continues, various design challenges arise. One of the often overlooked challenges is that of heat dissipation. Most often, this phase of design is neglected or added as a last minute consideration before the units are produced. According to the second law of thermodynamics, the more work that is performed in a closed system, the higher entropy it will attain. With the increasing power of a CPU, the larger flow of electrons produces a greater amount of heat. Therefore, in order to prevent the circuitry from shorting or burning out, the heat resulting from the increase in entropy must be removed.

A typical semiconductor chip contains closely packed metal conductors (e.g., Al, Cu) and ceramic insulators (e.g., oxide, nitride). The thermal expansion of metal is typically 5-10 times that of ceramics. When the chip is heated to above 60° C., the mismatch of thermal expansion capacities between metal and ceramics can create microcracks. The repeated cycling of temperature tends to aggravate the damage to the chip. As a result, the performance of the semiconductor will deteriorate. Moreover, when temperatures reach more than 90° C., the semiconductor portion of the chip may become a conductor so the function of the chip is lost. In addition, the circuitry may be damaged and render the semiconductor no longer usable (i.e. it becomes “burned out”). Thus, in order to maintain the performance of the semiconductor, its temperature must be kept below a threshold level of about 90° C.

Some state-of-the-art CPUs can have a power exceeding 120 watts (W). Current methods of heat dissipation, such as by using metal (e.g., Al or Cu) fin radiators, and water evaporation heat pipes, have proved inadequate to sufficiently cool recent generations of CPUs.

Recently, ceramic heat spreaders (e.g., AlN) and metal matrix composite heat spreaders (e.g., SiC/Al) have been used to cope with the increasing amounts of heat generation. However, such materials have a thermal conductivity that is no greater than that of Cu; hence, their ability to dissipate heat from semiconductor chips is limited.

Another conventional method of heat dissipation is to contact the semiconductor with a metal heat sink. A typical heat sink is made of aluminum that contains radiating fins. These fins are attached to a fan. Heat from the chip will flow to the aluminum base and will be transmitted to the radiating fins and carried away by the circulated air via convection. Heat sinks are therefore often designed to have a high heat capacity to act as a reservoir to remove heat from the heat source.

Alternatively, a heat pipe may be connected between the heat sink and a radiator that is located in a separate location. The heat pipe contains water vapor that is sealed in a vacuum tube. The moisture will be vaporized at the heat sink and condensed at the radiator. The condensed water will flow back to the heat sink by the wick action of a porous medium (e.g., copper powder). Hence, the heat of a semiconductor chip is carried away by evaporating water and removed at the radiator by condensing water.

Although heat pipes and heat plates may remove heat very efficiently, the complex vacuum chambers and sophisticated capillary systems associated therewith prevent designs small enough to dissipate heat directly from a semiconductor component. As a result, these methods are generally limited to transferring heat from a larger heat source, e.g., a heat sink. Thus, removing heat via conduction from an electronic component is a continuing area of research in the industry.

One promising alternative that has been explored for use in heat spreaders is diamond containing materials. Diamond can conduct heat much faster than any other material. The ability for diamond to transfer heat from a heat source without storing the heat makes diamond an ideal heat spreader. In contrast to heat sinks, a heat spreader acts to quickly conduct heat away from the heat source without storing it.

While diamond exhibits properties that make it attractive for use in heat spreaders, it proves problematic in particular areas. For example, heat spreaders comprised primarily of diamonds are very expensive, a consideration that becomes more relevant as the power rating of CPUs becomes increasingly larger. Also, as diamond exhibits a very low thermal expansion coefficient, it is often difficult to “match” a diamond heat spreader with the effective coefficient of a heat source. If a great variance in values exists between the thermal expansion coefficient of a heat spreader and a heat source, it is very difficult to reliably bond or couple the heat spreader to the heat source and thermal expansion and contraction of the heat source can compromise the bond between the two.

### SUMMARY OF THE INVENTION

Accordingly, the present invention provides composite heat spreaders that can be used to draw or conduct heat away from a heat source. In one aspect, a carbonaceous composite heat spreader includes a plurality of diamond grits present in an amount greater than about 50% by volume of the heat spreader and a metal matrix containing at least 50% aluminum by volume, holding the diamond grits in a consolidated mass.

In accordance with another aspect of the invention, the composite heat spreader includes a quantity of graphite, with the plurality of diamond grits being in substantially intimate contact with the graphite and with the metal matrix holding the graphite and the diamond grits in a consolidated mass.

In accordance with another aspect of the invention, the quantity of graphite comprises at least two distinct layers of graphite and the diamond grits are arranged in a layer disposed between the layers of graphite.

In accordance with another aspect of the invention, the quantity of graphite is in a form selected from the group consisting of: milled graphite fiber; long graphite fiber; chopped graphite fiber; graphite foil; graphite sheet; graphite mat; and graphite foam.

In accordance with another aspect of the invention, the aluminum includes an alloy selected from the group consisting of: Al—Mg; Al—Si; Al—Cu; Al—Ag; Al—Li; and Al—Be and mixtures thereof.

In accordance with another aspect of the invention, the metal matrix includes an element to reduce the melting point of the metal matrix, the element being selected from the group consisting of: Mn; Ni; Sn; and Zn.

In accordance with another aspect of the invention, a carbonaceous composite heat spreader is provided, including a heat conducting anisotropic carbonaceous material mixed with a heat conducting isotropic carbonaceous material, and a non-carbonaceous isotropic material substantially holding the anisotropic carbonaceous material and the isotropic carbonaceous material in a consolidated mass.

In accordance with another aspect of the invention, a method of removing heat from a heat source is provided, including the steps of: obtaining or providing a heat spreader as recited herein; and placing the heat spreader in thermal communication with the heat source.

In accordance with another aspect of the invention, a method of simulating isotropic heat flow through a graphite heat spreader is provided, including the steps of: disposing at least two quantities of graphite within a metal matrix, the quantities of graphite being at least partially separated by a portion of the metal matrix; disposing at least one diamond grit between the distinct quantities of graphite such that the diamond grit forms an isotropic thermal path through the metal matrix and between the distinct quantities of graphite.

Additionally, a diamond composite heat spreader can be used to draw or conduct heat away from a heat source. In one aspect, a diamond composite heat spreader can include a plurality of discrete diamond particles packed together. The heat spreader can further include sintered polycrystalline diamond dispersed throughout the diamond particles. The dispersed sintered polycrystalline diamond can at least partially cement the plurality of diamond particles together. Similarly, a diamond composite heat spreader can include a sintered polycrystalline diamond mass having a plurality of discrete diamond particles dispersed throughout the mass and at least partially held together by the mass. The discrete diamond particle can have sintering conditions different from sintering conditions of the sintered polycrystalline diamond mass.

Methods of making such diamond composite heat spreaders can include assembling a first plurality of diamond particles. A second plurality of diamond particles, of a smaller size, can be provided to at least partially fill in voids between the first plurality of diamond particles. The method can then include sintering the second plurality, or smaller, diamond particles to at least partially cement the plurality of diamond particles together. In another embodiment, a method for making a diamond composite heat spreader can include assembling a first plurality of diamond particles having a first set of consolidating conditions, and cementing the particles with a polycrystalline diamond material that has a second set of consolidating conditions that are different from the conditions of the first plurality of diamond particles.

There has thus been outlined, rather broadly, various features of the invention so that the detailed description thereof that follows may be better understood, and so that the present contribution to the art may be better appreciated. Other features of the present invention will become clearer from the following detailed description of the invention, taken with the accompanying claims, or may be learned by the practice of the invention.

### BRIEF DESCRIPTION OF THE DRAWINGS

FIG. 1 is a schematic, cross sectional side view of a heat spreader and a heat source in accordance with an embodiment of the present invention;

FIG. 2 is a schematic, cross sectional side view of a heat spreader and a heat source in accordance with an embodiment of the invention, the heat spreader having anisotropic carbonaceous material oriented therethrough in a random distribution;

FIG. 3 is a schematic, cross sectional side view of a heat spreader and a heat source in accordance with an embodiment of the invention, the heat spreader having anisotropic carbonaceous material oriented therethrough in a uniform direction.

FIG. 4 is a schematic, cross sectional side view of a heat spreader and a heat source in accordance with an embodiment of the invention, the heat spreader having anisotropic carbonaceous material oriented therethrough in a direction orthogonal to the anisotropic material of FIG. 3;

FIG. 5 is a schematic, cross sectional side view of a heat spreader and a heat source in accordance with an embodiment of the invention, the heat spreader having layers of anisotropic carbonaceous material and isotropic carbonaceous particles disposed therein; and

FIG. 6 is a schematic, cross sectional side view of a heat spreader and a heat source in accordance with an embodiment of the invention, the heat spreader having layers of isotropic carbonaceous particles of varying concentration disposed therein.

It will be understood that the above figures are merely for illustrative purposes in furthering an understanding of the invention. Further, the figures are not drawn to scale and components shown may not be accurately sized in relation to other components; thus dimensions, particle sizes, and other aspects may, and generally are, exaggerated to make illustrations thereof more clear. Therefore, departure can be made from the specific dimensions and aspects shown in the figures in order to produce the heat spreaders of the present invention.

### DETAILED DESCRIPTION

Before the present invention is disclosed and described, it is to be understood that this invention is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

It must be noted that, as used in this specification and the appended claims, the singular forms “a,” “an” and, “the” include plural referents unless the context clearly dictates otherwise. Thus, for example, reference to “a diamond particle” includes one or more of such particles, reference to “an interstitial material” includes reference to one or more of such materials, and reference to “the particle” includes reference to one or more of such particles.

Definitions

In describing and claiming the present invention, the following terminology will be used in accordance with the definitions set forth below.

As used herein, “particle” and “grit” may be used interchangeably, and when used in connection with a carbonaceous material, refer to a particulate form of such material. Such particles or grits may take a variety of shapes, including round, oblong, square, euhedral, etc., as well as a number of specific mesh sizes. As is known in the art, “mesh” refers to the number of holes per unit area as in the case of U.S. meshes. All mesh sizes referred to herein are U.S. mesh unless otherwise indicated. Further, mesh sizes are generally understood to indicate an average mesh size of a given collection of particles since each particle within a particular “mesh size” may actually vary over a small distribution of sizes. As far as is presently known, the only limitation as to mesh size of the particles or grits used in the present heat spreaders is that which is functional.

As used herein, “highly-packed” when describing particles indicates that a majority of the particles are in contact with another particle.

The term “discrete” in reference to a particle or particles indicates a definite particle having defined particle boundaries.

As used herein, “substantial,” or “substantially” refers to the functional achievement of a desired purpose, operation, or configuration, as though such purpose or configuration had actually been attained. Therefore, carbonaceous particles that are substantially in contact with one another function as though, or nearly as though, they were in actual contact with one another. In the same regard, carbonaceous particles that are of substantially the same size operate, or obtain a configuration as though they were each exactly the same size, even though they may vary in size somewhat.

As used herein, “heat spreader” refers to a material which distributes or conducts heat and transfers heat away from a heat source. Heat spreaders are distinct from heat sinks which are used as a reservoir in which heat is to be held, until the heat can be transferred away from the heat sink by another mechanism, whereas a heat spreader may not retain a significant amount of heat, but merely conducts heat away from a heat source.

As used herein, “heat source” refers to a device or object having an amount of thermal energy or heat which is greater than desired. Heat sources can include devices that produce heat as a byproduct of their operation, as well as objects that become heated to a temperature that is higher than desired by a transfer of heat thereto from another heat source. One non-limiting example of a heat source with which the present invention can be utilized is a central processing unit (“CPU”) commonly found in a variety of computers.

As used herein, “carbonaceous” refers to any material which is made primarily of carbon atoms. A variety of bonding arrangements, or “allotropes,” are known for carbon atoms, including planar, distorted tetrahedral, and tetrahedral bonding arrangements. As is known to those of ordinary skill in the art, such bonding arrangements determine the specific resultant material, such as graphite, diamond-like carbon (DLC), or amorphous diamond, and pure diamond. In one aspect, the carbonaceous material may be diamond.

As used herein “wetting” refers to the process of flowing a molten metal across at least a portion of the surface of a carbonaceous particle. Wetting is often due, at least in part, to the surface tension of the molten metal, and may be facilitated by the use or addition of certain metals to the molten metal. In some aspects, wetting may aid in the formation of chemical bonds between the carbonaceous particle and the molten metal at the interface thereof when a carbide forming metal is utilized.

As used herein, the terms “chemical bond” and “chemical bonding” may be used interchangeably, and refer to a molecular bond that exerts an attractive force between atoms that is sufficiently strong to create a binary solid compound at an interface between the atoms. Chemical bonds involved in the present invention are typically carbides in the case of diamond superabrasive particles, or nitrides or borides in the case of cubic boron nitride.

As used herein, “grade” refers to the quality of diamond particle. Higher grade indicates diamonds with fewer imperfections and inclusions. Synthetically-made diamonds are more likely than natural diamonds to include inclusions as a result of the manufacturing process. Diamonds with fewer imperfections and inclusions are better thermal conductors and therefore are preferably used in certain embodiments in the present invention. Additionally, diamonds with imperfections and inclusions are more prone to damage under certain manufacturing conditions. Selecting diamonds of a higher grade indicates conscious selection of diamond particles beyond selection for such qualities as size, price, and/or shape. Higher grade diamonds or diamonds of a high grade represents at least one step above the lowest available grade diamond particles, and often represents more than one step above. Such increase in grade is generally indicated by an increase in price when compared to diamond particles of the same size. Examples of high or higher grade diamond particles include Diamond Innovations MBS-960, Element Six SDB1100, and Iljin Diamond ISD1700.

Concentrations, amounts, particle sizes, volumes, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited.

As an illustration, a numerical range of “about 1 micrometer to about 5 micrometers” should be interpreted to include not only the explicitly recited values of about 1 micrometer to about 5 micrometers, but also include individual values and sub-ranges within the indicated range. Thus, included in this numerical range are individual values such as 2, 3, and 4 and sub-ranges such as from 1-3, from 2-4, and from 3-5, etc. This same principle applies to ranges reciting only one numerical value. Furthermore, such an interpretation should apply regardless of the breadth of the range or the characteristics being described.

The Invention

The present invention encompasses devices, systems, and methods for transferring heat away from a heat source. Heat spreaders made in accordance with the present invention generally include a plurality of diamond grits present in an amount greater than about 50% by volume of the heat spreader. A metal matrix containing at least 50% aluminum by volume can hold the diamond grits in a consolidated mass.

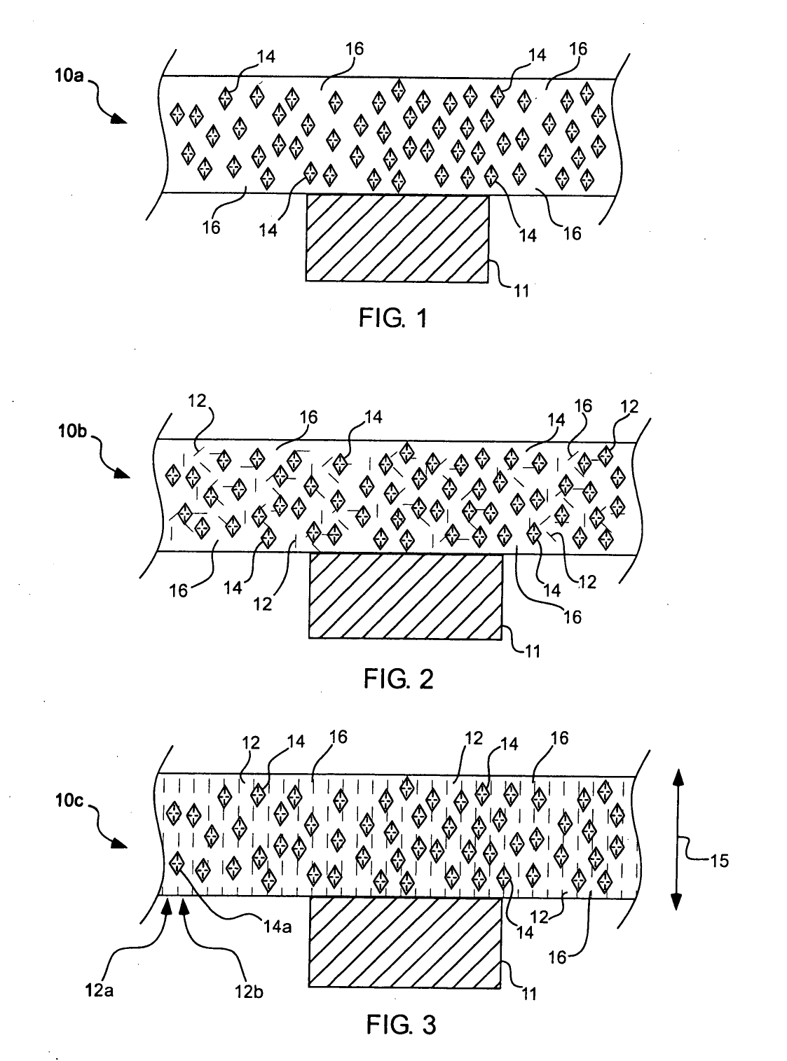

One exemplary heat spreader formed in accordance with the present invention is shown generally at 10a in FIG. 1. In this aspect of the invention, the composite heat spreader can include a heat conducting isotropic carbonaceous material 14 which can include, for example, a plurality of diamond grits. The diamond grits can be present in an amount greater than about 50% by volume of the heat spreader. In some aspects, the diamond grits can be present in an amount of from about 30% to about 95% by volume. In yet other aspects, the diamond grits can be present in an amount of from about 40% to about 60% by volume. A non-carbonaceous isotropic material 16 can hold the diamond grits in a consolidated mass. The non-carbonaceous isotropic material can include, for example, a metal matrix containing at least 50% aluminum by volume.

While in one embodiment the metal matrix 16 includes aluminum, it is to be understood that the metal matrix can include a variety of materials, including various metals and alloys. In the embodiment in which the matrix primarily includes aluminum, or alloys thereof, the metal matrix will generally be a much less expensive material than the diamond grits 14. However, the aluminum will also generally include a thermal conductivity that, while adequate for use in a heat spreader, is much less than that of the diamond grits. Thus, while aluminum may generally tend to conduct heat much more slowly than do the diamond grits, aluminum has been found to be a cost effective binder to hold the diamond grits in a consolidated mass and still provide acceptable heat transfer performance. In this manner, it is not necessary to form the entire heat spreader from diamond particles, enabling production of much cheaper heat spreaders that can be formed in much larger sizes than many diamond composite heat spreaders.

In addition to the relatively low cost of aluminum, aluminum has also proven effective for use in the metal matrix 16 due to its ability to wet diamond (and, as discussed in more detail below, graphite) during the aluminum infiltration process. As molten aluminum is infiltrated about the diamond and graphite elements of the heat spreaders disclosed herein, the aluminum wets the diamond or graphite and forms aluminum carbide while chemically bonding with the diamond or graphite. As a result, any voids or air pockets within the heat spreader will be significantly minimized, if not eliminated altogether. The minimization of air pockets or voids within the heat spreader is an important consideration in that the presence of even very small pores within the heat spreader can significantly reduce an overall thermal conductivity of the heat spreader. Accordingly, in one aspect, the heat spreader device of the present invention may be substantially free of voids or unfilled interstitial spaces between carbonaceous particles.

The formation of carbide is also, in some embodiments, advantageous in that it can increase the mechanical strength of the composite. By increasing the mechanical properties of the heat spreader, the heat spreader is better able to withstand inadvertent impacts and vibratory forces. Also, as attaching the heat spreader to a heat source is often done by force, higher strength heat spreaders can be more easily and effectively press-fitted with or attached to heat sources.

Another advantage of the use of aluminum as the non-carbonaceous isotropic material 16 is the relatively low melting point of aluminum. For example, aluminum has a melting point of about 660° C., which is generally low enough that relatively low-cost processes can be utilized to produce the present heat spreaders. In the case where alloys of aluminum are used for the non-carbonaceous isotropic material, the melting point of the metal matrix can be reduced even further. For example Al—Mg melts at about 450° C. (at the eutectic composition with about 36%/wt Mg). One of the more suitable alloys for the present invention, Al—Si, melts at about 577° C. (at the eutectic composition with about 12.6%/wt of Si).

Similarly, by using an Al—Cu alloy, with Cu at about 32 wt/%, the melting point can be reduced to about 548° C. The use of copper in the aluminum binder can also result in increasing the overall thermal conductivity of the heat spreader, which can, of course, increase the efficiency of the heat spreader in removing heat from a heat source. Al—Ag, with Ag at about 26 wt/%, melts at about 567° C., with a similar increase of thermal conductivity of the heat spreader. Al—Li, with Li at about 7 wt/%, melts at about 598° C.

Use of alloys such as these allows the present heat spreaders to be produced using techniques that are relatively simple and inexpensive. For example, common steel molds treated with a release agent such as BN spray can be utilized at relatively low temperatures to form heat spreaders in accordance with the present invention. In addition, use of alloys with relatively low melting points results in far less degradation of the diamond grits used in forming the heat spreaders, as compared to conventional methods which require temperatures sufficiently large that diamond degradation is a major concern. As such, more diamond material is preserved and able to conduct heat with higher capacity.

In addition to utilizing an aluminum alloy with a relatively low melting point, the metal matrix can also include various elements that reduce an overall melting point of the matrix. Suitable elements for reducing the melting point of the matrix include Mn, Ni, Sn and Zn.

Turning now to FIG. 2, in one aspect of the invention the heat spreader 10b can include a quantity of anisotropic carbonaceous material, which can include, but is not limited to, quantities of graphite 12. In this embodiment, the isotropic carbonaceous material (e.g., the plurality of diamond grits 14) can be in substantially intimate contact with the graphite. The non-carbonaceous isotropic material (e.g., metal matrix 16) can hold the graphite and the diamond grits in a consolidated mass. In this embodiment of the invention, the quantities of graphite are shown with a random distribution and orientation within the heat spreader. As will be appreciated from FIGS. 3-6, however, the quantities of graphite can also be distributed within the heat spreader in a patterned, layered orientation.

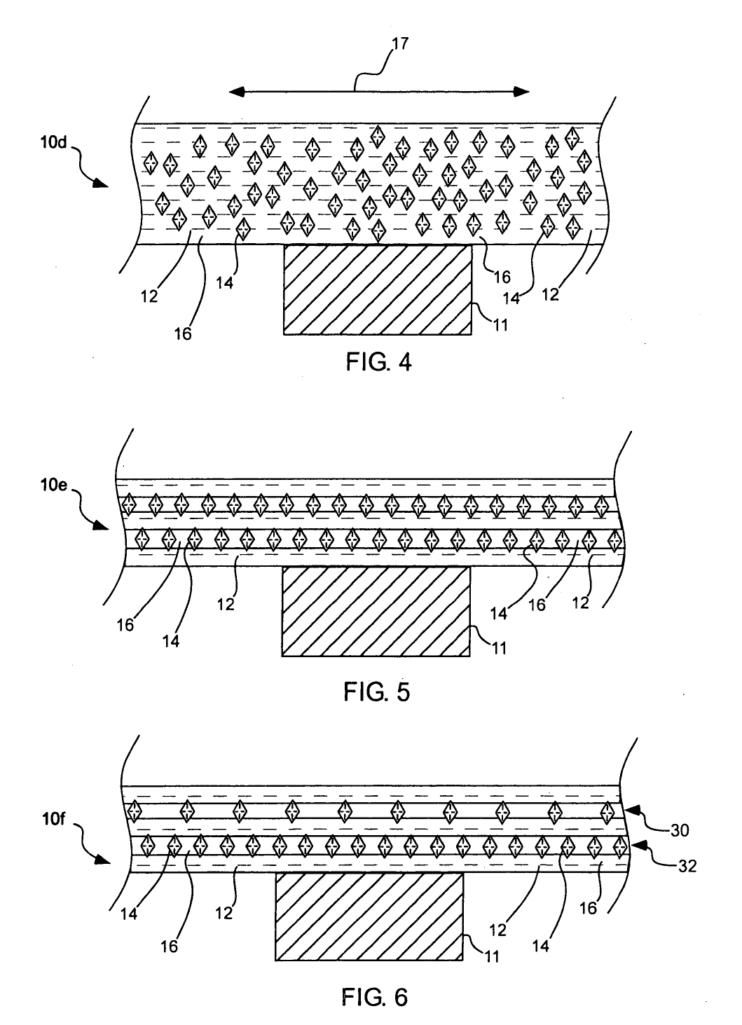

Regardless of the orientation of the graphite 12 within the heat spreader, the diamond grits 14 can allow graphite, which is an anisotropic material, to be utilized in a heat spreader designed to provide isotropic heat conduction from a heat source such as heat source 11 shown in each figure. As is well known, graphite exhibits a thermal conductivity approaching that of diamond in a direction along the length of a graphite plane, that is, in direction 15 parallel to the graphite layers or fibers of heat spreader 10c of FIG. 3 (and in direction 17 which is parallel to the graphite layers or fibers of heat spreader 10d in FIG. 4). However, the thermal conductivity of graphite in a direction orthogonal to the graphite plane (e.g., in a direction orthogonal to either direction 15 of FIG. 3 or 17 of FIG. 4), is so poor that graphite becomes an insulator for transfer of heat in this direction.

For this reason, it has generally been thought desirable for heat transmission purposes to orient graphite flakes or fibers parallel to the direction of heat flow from a heat source so that the heat may be conducted away from the heat source along the length of the graphite fibers. With reference to FIG. 3, for example, the graphite layers or fibers 12 would generally be oriented to conduct heat upwardly from heat source 11. However, while such an arrangement will allow the graphite to conduct heat along the graphite plane, heat is generally unable to flow laterally or horizontally across the heat spreader (e.g., orthogonally to direction 15 in FIG. 3). This is, of course, due to the fact that graphite is a thermal insulator in a direction orthogonal to direction 15 across or through the graphite plane.

Thus, even in the case where a relatively wide heat spreader containing graphite aligned parallel to the direction in which heat is to be removed from a heat source is used, localized “hot spots” in the heat source are not allowed to diffuse across the width of the entire heat spreader. Due to this problem, “bottlenecks” can occur in the conduction of heat along the graphite plane, as heat is being conducted away from the heat source by one, or only a few, graphite fibers or layers. As the few graphite fibers or layers which are conducting heat reach maximum heat conduction capacity, the heat spreader becomes limited by the few fibers or layers which are conducting heat, instead of being limited by the overall width of the heat spreader. Thus, even in cases where graphite fibers are properly aligned to conduct heat, use of anisotropic graphite in heat spreaders is a less than desirable solution to heat conduction problems.

The present invention addresses this shortcoming by the addition of a highly isotropic material, e.g., diamond grits, within or adjacent to the graphite to add a desired isotropic quality to the heat spreader as a whole. For example, the graphite flakes or fibers 12 shown in FIG. 4 extend generally parallel across the page and will therefore serve as an excellent heat spreader in direction 17. However, in the case where it is desired that the heat spreader conduct heat in a direction other than direction 15, the graphite will serve as an insulator against heat flow. The present invention addresses this problem by the introduction of diamond grits 14 within the matrix of graphite and metal matrix 16. The diamond grits serve as thermal paths, or bridges, through which heat can flow to provide isotropic heat flow through the spreader as a whole, regardless of the orientation of the graphite fibers within the heat spreader. In this manner, heat can flow freely along the plane of graphite material until a diamond particle is reached. The heat may then flow through the diamond particle to additional graphite materials where it can once again flow along the plane thereof.

The diamond grits 14 can be used with a random distribution of graphite 12, as shown in FIG. 2, or with a more ordered distribution of graphite, as shown in FIGS. 3-6. For example, as shown in FIG. 3, in one aspect of the invention, the quantity of graphite can include at least two distinct layers of graphite, layer 12a and layer 12b. Diamond grit 14a can form a thermal path between layers 12a and 12b of the graphite. In this manner, as heat flows through either of layer 12a or 12b, diamond grit 14a allows heat to flow freely from one layer to another. As diamond grit 14a generally includes a thermal conductivity equal to or greater than that of each of the graphite layers, the diamond grit reduces the formation of heat flow “bottlenecks” in the layers of graphite. In this manner, heat is conducted at a relatively high rate along the graphite fibers or layers, and is also conducted at a relatively high rate between graphite fibers or layers through the diamond grit. Thus, the heat spreader performs more like a heat spreader formed of an isotropic material than one formed of an anisotropic material.

As discussed above, the graphite used in the present invention can be of a variety of forms, including milled graphite fiber, long graphite fiber, chopped graphite fiber, graphite foil, graphite sheet, graphite mat, graphite foam, and mixtures thereof. Commonly available graphite materials, such as sheets produced under the tradename “Graphoil” can also be used.

The present invention thus utilizes a combination of anisotropic and isotropic materials to provide a heat spreader that exhibits isotropic properties overall. In this manner, relatively low-cost graphite can be used in much of the heat spreader body, with the addition of much less diamond content than in conventional diamond heat spreaders. As the diamond grits are isotropic, and generally have a higher thermal conductivity than does graphite, the positioning of the diamond grits between fibers of the graphite does not impede heat flow through the fibers while distributing heat between and to adjacent fibers.

While not so required, at least some of the diamond grits can be embedded in a distinct quantity of the heat conducting anisotropic carbonaceous material (e.g., graphite). By embedding the diamond grits in the distinct quantities of graphite, the interface area between the diamond grits and the graphite can be maximized to reduce blockage of heat flow between the diamond grits and the graphite.

The creation of thermal paths through the heat spreader by diamond grits spanning layers of graphite can be done in a random manner, as would be the case where the diamond grits are distributed randomly through the graphite layer. In addition, it is contemplated that the diamond grits can be intentionally distributed throughout the heat spreader in a desired pattern to meet a particular heat spreading application.

For example, FIG. 5 illustrates an embodiment of the invention in which layers of both diamond particles or grit 14 and graphite 12 are stacked to produce a uniform pattern of diamonds and graphite fibers. In this exemplary embodiment, the heat spreader 10e can be formed by first placing a layer of graphite in the bottom of a suitable mold (not shown). The layer of graphite can include a “preform” sheet which includes a plurality of graphite fibers held together by a suitable binder. A layer of diamond grits can then be stacked upon the layer of graphite. The diamond grits can similarly be formed in preform sheets, held with a suitable binder, to enable a consistent layer of diamond grits to be applied. Successive layers of graphite and diamond can be added to create a heat spreader having a desired thickness or height.

Once the desired amount of graphite and diamond grits have been placed, the mold can be heated as molten aluminum or aluminum alloy (or another suitable non-carbonaceous isotropic material) is applied to the diamond grits and graphite. As the aluminum infiltrates the diamond grits and graphite, the materials are consolidated into a mass with substantially all voids between the diamond and the graphite being filled with aluminum. As discussed above, the aluminum can also form carbides during the infiltration process.

Heat spreaders of the present invention can be used in connection with a variety of heat sources (none of which are shown in the figures, as examples of such heat sources typified by CPUs are well known to those of ordinary skill in the art). While not so limited, heat spreaders of the present invention can be used to transfer or conduct heat from a variety of appliances where a relatively low-cost heat spreader that can be easily formed into large shapes is desired.

One advantage to the heat spreaders of the present invention is the ability to alter the constituent makeup of the heat spreaders to aid in matching a thermal expansion coefficient of a particular heat source. This can be beneficial in that the heat spreader and the heat source can expand and contract at similar rates to avoid compromising the bond between the heat source and the heat spreader. As the heat spreaders of the present invention involve three primary materials; diamond, graphite and aluminum, the overall coefficient of thermal expansion of the present heat spreaders can be adjusted in three degrees of freedom. Thus, by adjusting the concentration of any of the three materials, the overall coefficient of thermal expansion can be adjusted.

FIG. 6 illustrates another embodiment of the invention in which a thermal conductivity gradient is formed within heat spreader 10f by forming one layer 32 of diamond grits having a greater concentration of diamond grits than another layer 30 of diamond grits. By providing a variable thermal conductivity gradient in the heat spreader 10f, more diamond material can be selectively used in a region closer to a heat source (e.g., layer 32 which is closer to heat source 11) while allowing for less diamond material to be used in a region farther from the heat source (e.g., in layer 30). In this manner, areas in which available volumes may be larger (and thus not require a high degree of thermal conductivity) can contain fewer high-cost materials without sacrificing overall performance of the heat spreader. Similar effects can be achieved by altering the concentration of diamond grits in a particular layer by utilizing diamond grits of greater or lesser mesh size.

This aspect of the invention can be advantageous when it is desired to spread heat from a very localized area (e.g., a “hot spot”) to a heat spreader with relatively larger surface area. This embodiment of the invention can be utilized with heat spreaders disclosed in Applicant's copending U.S. patent application Ser. No. 10/775,543, filed Feb. 9, 2004, which is hereby incorporated herein in its entirety.

In addition to the applications disclosed herein, the present invention can be used in connection with a cooling system for transferring heat away from a heat source. Examples of cooling systems within which the present invention can be incorporated are disclosed in Applicant's copending U.S. patent application Ser. No. 10/453,469 filed Jun. 2, 2003, which is hereby incorporated herein in its entirety.

In a specific embodiment, a heat spreader can include diamond. A diamond composite heat spreader can include a plurality of discrete diamond particles packed together. The heat spreader can further include sintered polycrystalline diamond dispersed throughout and at least partially cementing the plurality of diamond particles together. In another embodiment, a diamond composite heat spreader can include a sintered polycrystalline diamond mass with a plurality of discrete diamond particles that have sintering conditions different from the sintering conditions of the polycrystalline diamond mass. The discrete diamond particles can be dispersed throughout and partially or wholly held together by the sintered polycrystalline diamond mass.

In one aspect, the sintered polycrystalline diamond can cement the plurality of diamond particles together. As with other embodiments, the diamond particles can be arranged in any manner. Such diamond particles can be ordered, or in a pattern, or can be sporadically arranged. In cases of patterning or deliberate arrangement, the pattern or arrangement can extend in a plane or a three-dimensional configuration. In one aspect, some of the diamond particles can be in contact with other diamond particles. In a specific configuration, the diamond particles can be highly-packed, meaning a majority of the diamond particles are in contact with another diamond particle. In a further configuration, the diamond particles can be contact each other sufficiently to provide a continuous diamond-to-diamond path to substantially each of the diamond particles.

The sintered polycrystalline diamond can be a single mass or can include a plurality of sintered polycrystalline diamond masses. The sintered polycrystalline diamond can be responsible for a little or all of the mechanical locking, or cementing, of the discrete particles. The cementing can be assisted by the inclusion of additional materials. Alternatively, the sintered polycrystalline diamond be solely responsible for cementing the discrete diamond particles.

Another design consideration, as noted above, is the amount of diamond particles present in the heat spreader. Selection of the amount of diamond particles can depend greatly on the intended purpose of the heat spreader, manufacturing restrictions, and cost. In one configuration, diamond particles can be present in an amount of between 10% and 80% by volume of the heat spreader. In a higher-grade heat spreader design, between about 70% and about 98% by volume of the heat spreader can be discrete diamond particles.

To increase the thermal conductivity of the heat spreader, higher grade diamond particles can be used. The thermal conductivity of diamond grit is not necessarily higher than metallic materials, such as copper, if the diamond contains inclusions and other forms of defects. Diamond particles of better quality can transmit heat much faster than poorer-quality diamond particles. Thus, use of higher grade diamond particles increases the overall thermal conductivity of the heat spreader. Regularly-shaped diamonds may also increase the thermal conductivity of a heat spreader. As such, it may be desirable in some designs to include diamonds of regular shape. The diamond particles can be arranged so as to promote thermal conduction and transfer. To enhance thermal conduction and transfer, a diamond particle can be in direct physical contact with another diamond particle. Such contact, as mentioned above, is diamond-to-diamond contact. In one embodiment, substantially all diamond particles of a layer or substantially throughout the entire heat spreader can be in diamond-to-diamond contact. Therefore, substantially all diamond particles in the heat spreader can be in direct physical contact with at least one other diamond particle. In yet another embodiment, substantially all diamond particles may be in contact with one or more diamond particles to the extent that a continuous diamond particle path way is provided for heat flow. In other words, all diamond particles are in substantial contact with the body or assembly of diamond particles provided. In an alternate embodiment, the diamond particles can be arranged or tiled in a two-dimensional pattern. In one example, the diamond particles can be substantially equidistant from each other. In a further embodiment, the tiled diamond particles can be in diamond-to-diamond contact. The diamond particles can be configured to have the same or similar orientations, which can further enhance the above embodiments, and thus improve thermal conductivity. In such embodiment, the tiling can be configured to minimize the gaps in between diamond particles. For example, the diamond particles can have a plane wherein all particles align on their faces. Where the diamond particles are of the same size, there may be two planes wherein the diamond particles align on their faces, i.e. a top and a bottom plane of the single diamond layer. Such layer can be partially exposed from the heat spreader in some embodiments, or may be substantially surrounded by cementing material, for example the polycrystalline diamond and/or an interstitial material.

Size can also affect the ability of diamond particles to transmit heat. Larger diamond particles perform much better than their smaller counterparts. Likewise, uniform diamond particles improve the ability of the single layer of diamond particles to transmit heat. As such, one embodiment of the present invention contemplates diamond particles that are substantially uniform in size. Although the size of the diamond particles can be of any size, in one embodiment, the diamond particles can be greater than about 150 μm, or greater than about 300 μm. In some aspects, particles of 30/40 mesh are used in combination with other particles or exclusively; likewise, in other aspects particles of 40/50 mesh are used in combination with other particles or exclusively. In a particular embodiment, coarser diamond particles can be used, such as those larger than about 60 mesh or larger than 80mesh.

A diamond composite heat spreader can include a non-diamond interstitial material, as discussed herein. Such material can assist the polycrystalline diamond in cementing the diamond particles. Interstitial material can improve the conductivity of the heat spreader by infiltrating voids in the heat spreader. Further, the interstitial material can act as a diamond-to-diamond sintering aid in improving sintering of the polycrystalline diamond. Note, however, that such sintering of the polycrystalline diamond works to cement the discrete diamond particles, where the discrete diamond particles maintain defined particle boundaries. In a specific embodiment, the interstitial material can comprise or consist essentially of silicon, or an alloy thereof. Non-limiting examples of interstitial materials include Ag, Cu, Al, Si, Fe, Ni, Co, Mn, W, Ti, Cr, and mixtures and alloys thereof. Interstitial material can be introduced into the heat spreader a variety of ways, such as, e.g., mixing and/or infiltration. In an alternate configuration, the heat spreader can be substantially devoid of non-diamond material. Therefore, the heat spreader can consist essentially of diamond.

Heat spreaders can be of any size and shape. A particular useful design includes a heat spreader having a thickness of at least 1 mm.

A variety of methods for making diamond composite heat spreaders are presently contemplated. In a specific embodiment, the method can include assembling a plurality of diamond particles and providing a second plurality of smaller diamond particles that at least partially fills the voids between the first plurality of diamond particles. The second plurality of diamond particles can be sintered to at least partially cement the plurality of diamond particles together. The first plurality of diamond particles can remain as discrete particles throughout processing as well as in the final product. In another method, a first plurality of diamond particles having a first set of consolidating conditions can be assembled and then cemented with a polycrystalline diamond material that has a second set of consolidating conditions that are different from the first set of consolidating conditions. Consolidating conditions reflect the conditions necessary to induce and/or maintain sintering of the diamonds. Variables of the conditions include, e.g., temperature, pressure, particle size, and presence of additional materials. The second plurality of diamond particles can be any size in relation to the first plurality of diamond particles. Typically, the second plurality of particles is smaller, on average, than the first plurality of particles. The size difference can vary depending on the intended use, availability of materials and manufacturing method. In one aspect, the second plurality of particles can have a diameter of between about 1/15^{th} and about 1/10^{th} of the diameter of the first plurality of diamond particles. In a specific embodiment, the second plurality of diamond particles can comprise or consist essentially of nano-diamonds. In another embodiment, the second plurality of diamond particles can comprise or consist essentially of micron-diamonds.

The sintering of either embodiment can be accomplished by a variety of mechanisms. In one aspect, the sintered polycrystalline diamond can be sintered by hot pressing. In another aspect, microwave sintering can be used to sinter. In some embodiments, the manufacture of the heat spreader can include injection molding. To efficiently form a diamond composite heat spreader, the injection molding equipment can be reinforced against the abrasive nature of the diamond particles. The second plurality of diamond particles which form the polycrystalline diamond can be of a relatively small size, as would require lower pressure and/or temperature to consolidate. Additionally, the diamond particles may be mixed and manufactured easier by the inclusion of additional materials, such as binder.

The step of assembling in any of the noted embodiments can include packing diamonds to any level. In some aspects, such packing can result in a highly-packed arrangement, or a diamond-to-diamond arrangement. In a specific aspect, the diamonds can be packed to over 50% by volume of the heat spreader prior to providing the second plurality of diamond particles. Such arrangement allows for a greater amount of the first plurality of diamond particles. The second plurality of diamond particles can at least partially fill in voids between the first plurality of diamond particles to form a packed collection of diamonds between about 50% and about 99% by volume of diamond.

In addition to the structure disclosed above, the present invention also provides a method of removing heat from a heat source, comprising the steps of: obtaining a heat spreader as recited in the above discussion; and placing the heat spreader in thermal communication with the heat source. Heat sources can vary, but specifically include one or more CPUs.

Additional configurations, manufacturing methods, designs, materials for inclusion, manufacturing conditions, and potential uses are discussed in copending applications Ser. No. 11/056,339, filed Feb. 10, 2005; and Ser. No. 11/266,015 filed Nov. 2, 2005; and U.S. Pat. Nos. 7,173,334, 6,984,888, and 6,987,318 and each are applicable to the present disclosure.

In one embodiment of the invention, as shown for example in FIGS. 5 and 6, graphite is incorporated into the heat spreader with a layer of graphite comprising the surface of the heat spreader which is to be attached or disposed immediately adjacent to a heat source. In this aspect of the invention, as graphite is a relatively soft material, the heat spreader can be pressed onto or over a heat source and the heat spreader can be at least partially deformed about a geometric feature of the heat source (not shown in the figures). In this manner, the heat spreader can be “friction fitted” to the heat source to eliminate or reduce the need for attachment mediums often used to attach heat spreaders to heat sources. Thus, commonly used materials such as thermal grease can be advantageously avoided, and the added thermal impedance generally introduced by such materials can be eliminated.

In accordance with another aspect of the invention, a method of simulating isotropic heat flow through a graphite heat spreader is provided, including the steps of: disposing a plurality of diamond grits in thermal communication with graphite in the heat spreader such that the diamond grits enhance heat flow in a direction substantially impeded by the graphite.

### EXAMPLES

The following examples present various methods for making the heat spreaders of the present invention. Such examples are illustrative only, and no limitation on the present invention is meant thereby.

### Example 1

Preformed sheets of diamond and carbon fiber were obtained having a suitable organic binder which retained the diamond and carbon fiber in sheet form. The preformed sheets (or “performs”) were stacked in a steel die sprayed with a boron nitride release agent. Molten Al—Si, with a melting point of about 577° C., was pressed by a steel plunger until the alloy infiltrated through the mold. The molten alloy, which wetted both the diamond and the carbon fiber, filled substantially all voids between the diamond and carbon fiber to create a consolidated mass heat spreader.

The organic binder used with both the diamond and the carbon fiber was either vaporized or oxidized, or decomposed, during the aluminum infiltration stage. The organic binder was reduced to carbon residue that did not have an adverse affect on the final product.

The measured thermal conductivity of the resultant heat spreader was about 600 W/mK and the measured coefficient of thermal expansion was about 7.5 PPM/C.

### Example 2

Preformed sheets of a mixture of diamond and carbon fiber were obtained having a suitable binder used to retain the diamond and carbon fibers in sheet form. The preforms were stacked in a suitable mold after which molten Al—Si was infiltrated into and through the mold. The molten alloy, which wetted both the diamond and the carbon fiber, filled substantially all voids between the diamond and the carbon fiber to create a consolidated mass heat spreader. The binder used was either vaporized or oxidized, or decomposed during the aluminum infiltration stage.

The measured thermal conductivity of the resultant heat spreader was about 600 W/mK and the measured coefficient of thermal expansion was about 7.5 PPM/C.

It is, of course, to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

1. A diamond composite heat spreader, comprising:
a plurality of discrete and packed diamond particles; and
sintered polycrystalline diamond dispersed throughout and at least partially cementing the plurality of diamond particles together.

2. The heat spreader of claim 1, wherein the diamond particles are highy-packed.

3. The heat spreader of claim 1, wherein the diamond particles contact each other sufficiently to provide a continuous diamond-to-diamond path to substantially each of the diamond particles.

4. The heat spreader of claim 1, wherein the diamond particles are present in an amount of between about 10% and about 80% by volume of the heat spreader.

5. The heat spreader of claim 1, comprising between about 70% and about 98% by volume of diamond particles.

6. The heat spreader of claim 1, wherein the size of substantially all of the diamond particles is greater than about 150 μm.

7. The heat spreader of claim 6, wherein the size of substantially all of the diamond particles is greater than about 300 μm.

8. The heat spreader of claim 1, wherein substantially all of the diamond particles are high-grade.

9. The heat spreader of claim 1, further comprising a non-diamond interstitial material.

10. The heat spreader of claim 9, wherein the interstitial material is the result of infiltration.

11. (canceled)

12. The heat spreader of claim 9, wherein the interstitial material is a member selected from the group consisting of Ag, Cu, Al, Si, Fe, Ni, Co, Mn, W, Ti, Cr, and mixtures or alloys thereof.

13. (canceled)

14. (canceled)

15. The heat spreader of claim 12, wherein the sintered polycrystalline diamond is substantially a single mass.

16. The heat spreader of claim 1, wherein the sintering of the sintered polycrystalline diamond is accomplished by hot pressing or by microwave sintering.

17. The heat spreader of claim 1, wherein the polycrystalline diamond cements the plurality of diamond particles together.

18. (canceled)

19. The heat spreader of claim 1, wherein the heat spreader consists essentially of diamond.

20.-28. (canceled)

29. A method of making a diamond composite heat spreader comprising the steps of:
assembling a first plurality of diamond particles having a first average mesh size;
providing a second plurality of diamond particles at least partially filling voids between the first plurality of diamond particles, said second plurality of diamond particles having a second average mesh size smaller than the first average mesh size; and
sintering the second plurality of diamond particles sufficient to at least partially cement the plurality of diamond particles together.

30. The method of claim 29, wherein the providing and sintering the second plurality of diamond particles includes injection molding.

31.-33. (canceled)

34. The method of claim 29, wherein the second mesh size particles have a diameter of between about ⅕^{th} and about 1/10^{th} the diameter of the first average mesh size particles.

35. (canceled)

36. The method of claim 29, farther comprising the step of providing an interstitial material at least partially filling voids between the first plurality of diamond particles.

37.-40. (canceled)

41. A method of removing heat from a heat source comprising the steps of:
a) providing a heat spreader as recited in claims 1; and
b) positioning the heat spreader in operative connection with the heat source.
